(19) United States
(12) Patent Application Publication
(10) Pub. No.: US 2017/0140702 A1
(43) Pub. Date: May 18, 2017

(54) OLED PANEL, TERMINAL, AND METHOD FOR CONTROLLING PHOTOSENSITIVITY

(71) Applicant: Xiaomi Inc., Beijing (CN)

(72) Inventors: Guosheng LI, Beijing (CN); Guilin ZHONG, Beijing (CN); Wei FENG, Beijing (CN)

(73) Assignee: Xiaomi Inc., Beijing (CN)

(21) Appl. No.: 15/349,070

(22) Filed: Nov. 11, 2016

(30) Foreign Application Priority Data
Nov. 13, 2015 (CN) 201510779976.8

(51) Int. Cl. G09G 3/3208; H01L 27/32; H04N 5/225

(52) U.S. Cl. CPC G09G 3/3208; H04N 5/2257; H04N 5/2253; H01L 27/3248; H01L 27/3213; G09G 2300/0404

(57) ABSTRACT

The present disclosure provides OLED panels, terminals, and methods for controlling photosensitivity, and relates to the field of display technology. An OLED panel may include an array substrate and an OLED layer disposed on the array substrate. The OLED panel may further include a photosensitive device array disposed in the array substrate or disposed between the array substrate and the OLED layer. The OLED panel may further include a control circuit connected to the photosensitive device array.

### CROSS-REFERENCE TO RELATED APPLICATIONS

This application is based on and claims priority to Chinese Patent Application Serial No. 201510779976.8, filed on Nov. 13, 2015 with the State Intellectual Property Office of the People's Republic of China, the entire contents of which is incorporated herein by reference.

### TECHNICAL FIELD

The present disclosure relates to the field of display technology, and more particularly to organic light emitting display (OLED) panels, terminals, and methods for controlling photosensitivity.

### BACKGROUND

A camera is a common component in a mobile terminal. A camera is used for collecting an image. Cameras may be classified as front-facing cameras and rear-facing cameras depending upon their positions on the mobile terminal.

As an example, a mobile terminal may include a front panel that includes an OLED panel region, a frame region, and a front facing camera. In related art, the frame region is provided with an aperture in which the front-facing camera is installed.

### SUMMARY

In order to resolve a problem that a terminal needs to be provided with a separate aperture for a camera, the present disclosure provides organic light emitting display (OLED) panels, terminals, and methods for controlling photosensitivity. Technical solutions are shown below.

According to a first aspect of embodiments of the present disclosure, there is provided an organic light emitting display (OLED) panel. The OLED panel may include an array substrate and an OLED layer disposed on top of the array substrate. The OLED panel may further include a photosensitive device array disposed in the array substrate or disposed between the array substrate and the OLED layer. The OLED panel may further include a control circuit connected to the photosensitive device array.

According to a second aspect of embodiments of the present disclosure, there is provided a method for controlling photosensitivity with a photosensitivity control unit connected to an organic light emitting display (OLED) panel. The method may include sending an enabling signal to a control line in an i^{th} row of b rows of a plurality of control lines of the OLED panel, the enabling signal configured to control photosensitive devices in the i^{th} row to communicate with a data line of the OLED panel, wherein 0<i≦b. The method may further include obtaining, via the data line, a photosensitive signal collected by the photosensitive devices in the i^{th} row. The method may further include after sending the enabling signal to the control line in the i^{th} row, generating an updated value of i by, when i<b, setting the updated value of i=i+1, and by, when i=b, setting the updated value of i=1. The method may further include sending the enabling signal to a control line in an i^{th} row of the b rows of the plurality of control lines of the OLED panel, wherein i is the updated value of i.

According to a third aspect of embodiments of the present disclosure, there is provided a terminal. The terminal may include an organic light emitting display (OLED) panel. The terminal may further include a processor and a memory for storing instructions executable by the processor. The processor may be configured to send an enabling signal to a control line in an i^{th} row of b rows of a plurality of control lines of the OLED panel, the enabling signal configured to control photosensitive devices in the i^{th} row to communicate with a data line of the OLED panel, wherein 0<i≦b. The processor may be further configured to obtain, via the data line, a photosensitive signal collected by the photosensitive devices in the i^{th} row. The processor may be further configured to, after sending the enabling signal to the control line in the i^{th} row, generate an updated value of i by, when i<b, setting the updated value of i=i+1, and when i=b, setting the updated value of i=1. The processor may be further configured to send the enabling signal to a control line in an i^{th} row of the b rows of the plurality of control lines of the OLED panel, wherein i is the updated value of i.

Both the foregoing general description and the following detailed description are illustrative only and are not restrictive of the disclosure as described in the appended claims.

### BRIEF DESCRIPTION OF THE DRAWINGS

The accompanying drawings, which are incorporated in and constitute a part of this specification, illustrate embodiments consistent with the present disclosure and, together with the description, serve to explain principles of the present disclosure.

FIG. 1 is a schematic diagram showing an OLED panel in related art;

FIG. 2 is a schematic diagram showing an arrangement of pixel units of an array substrate;

FIG. 3A is a schematic diagram showing an OLED panel according to an illustrative embodiment of the present disclosure;

FIG. 3B is a schematic diagram showing an OLED panel according to an illustrative embodiment of the present disclosure;

FIG. 4A is a schematic diagram showing a position at which a photosensitive device is located according to an illustrative embodiment of the present disclosure;

FIG. 4B is a schematic diagram showing a position at which a photosensitive device is located according to an illustrative embodiment of the present disclosure;

FIG. 4C is a schematic diagram showing a position at which a photosensitive device is located according to an illustrative embodiment of the present disclosure;

FIG. 4D is a schematic diagram showing a position at which a photosensitive device is located according to another illustrative embodiment of the present disclosure;

FIG. 5 is a schematic diagram showing a control circuit according to an illustrative embodiment of the present disclosure;

FIG. 6A is a schematic diagram showing an OLED panel according to an illustrative embodiment of the present disclosure;

FIG. 6B is a schematic diagram showing an OLED panel according to an illustrative embodiment of the present disclosure;

FIG. 7 is a block diagram showing a terminal according to an illustrative embodiment of the present disclosure; and

FIG. 8 is a flow chart showing a method for controlling photosensitivity according to an illustrative embodiment of the present disclosure.

### DETAILED DESCRIPTION

Reference will now be made in detail to illustrative embodiments, examples of which are illustrated in the accompanying drawings. The following description refers to the accompanying drawings in which the same numbers in different drawings represent the same or similar elements unless otherwise noted. The implementations set forth in the following description of illustrative embodiments do not represent all implementations consistent with the disclosure. Instead, they are merely examples of apparatuses and methods consistent with aspects related to the disclosure as recited in the appended claims.

Reference throughout this specification to “one embodiment,” “an embodiment,” “exemplary embodiment,” or the like in the singular or plural means that one or more particular features, structures, or characteristics described in connection with an embodiment is included in at least one embodiment of the present disclosure. Thus, the appearances of the phrases “in one embodiment” or “in an embodiment,” “in an exemplary embodiment,” or the like in the singular or plural in various places throughout this specification are not necessarily all referring to the same embodiment. Furthermore, the particular features, structures, or characteristics in one or more embodiments may be combined in any suitable manner.

The terminology used in the description of the disclosure herein is for the purpose of describing particular examples only and is not intended to be limiting of the disclosure. As used in the description of the disclosure and the appended claims, the singular forms “a,” “an,” and “the” are intended to include the plural forms as well, unless the context clearly indicates otherwise. It will be understood that the term “or” as used herein refers to any one item of the associated list items, and all possible combinations of one or more of the associated list items, unless context clearly requires the term “or” to be exclusive. For example, a reference to “A or B” includes only A, only B, and both A and B, unless context clearly requires otherwise. It will also be understood that the term “and/or” as used herein refers to and encompasses any and all possible combinations of one or more of the associated listed items. It will be further understood that the terms “may include,” “including,” “comprises,” and/or “comprising,” when used in this specification, specify the presence of stated features, operations, elements, and/or components, but do not preclude the presence or addition of one or more other features, operations, elements, components, and/or groups thereof.

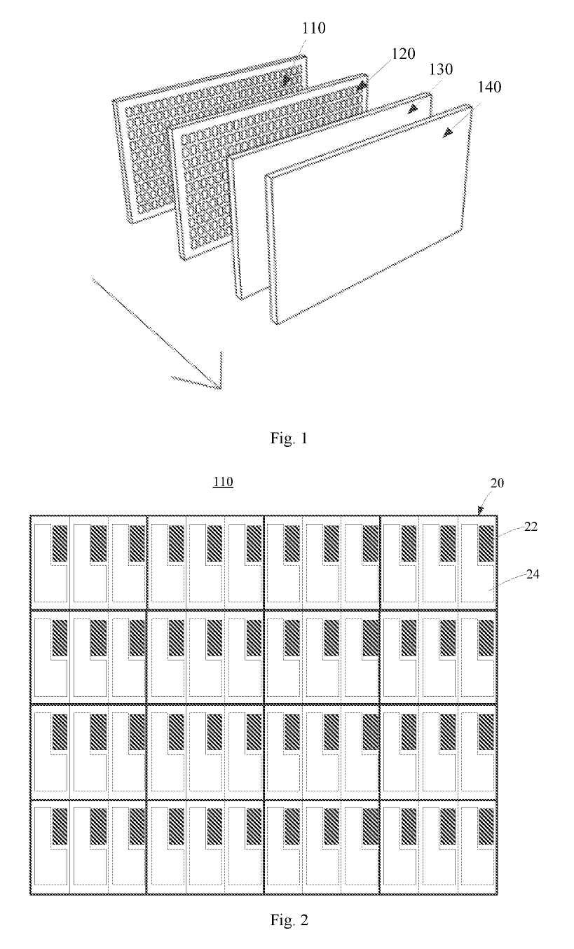

Before introducing and describing embodiments of the present disclosure, an organic light emitting display (OLED) panel is first briefly described. FIG. 1 is a schematic diagram showing an OLED panel in related art.

As shown in FIG. 1, an OLED panel may include: an array substrate 110, an OLED layer 120, a glass substrate 130, and a polarizer 140.

The OLED layer 120 is disposed on the array substrate 110, the glass substrate 130 is disposed on the OLED layer 120, and the polarizer 140 is disposed on the glass substrate 130.

The OLED layer 120 includes m×n pixel units. The symbol m represents columns of pixel units, and the symbol n represents rows of pixel units. Each pixel unit includes K respective pixel sub-units. In general, each pixel unit in the OLED layer 120 includes three pixel sub-units, which may be a red (R) pixel sub-unit, a green (G) pixel sub-unit, and a blue (B) pixel sub-unit. In some embodiments, each pixel unit includes four pixel sub-units, which may be a red (R) pixel sub-unit, a green (G) pixel sub-unit, a blue (B) pixel sub-unit, and a white (W) pixel sub-unit. Thus in exemplary embodiments, the number K may be three or four.

The array substrate 110 may also include m×n pixel units corresponding to the m×n pixel units in the OLED layer 120. Each pixel unit in the array substrate 110 includes K pixel sub-units, for example three pixel sub-units or four pixel sub-units.

FIG. 2 is a schematic diagram showing an arrangement of pixel units in the array substrate 110. As shown in FIG. 2, the array substrate 110 includes 4×4 pixel units, i.e., 16 pixel units, and each pixel unit includes three pixel sub-units 20. Each pixel sub-unit 20 includes a respective thin film transistor (TFT) region 22 and a respective non-TFT region 24.

Although FIG. 2 merely shows a single sub-region of the array substrate 110, the array substrate 110 may include a plurality of such sub-regions, arranged, for example, end-to-end and side-by-side to form a larger region with a similar pattern of pixel units and pixel sub-units. The arrangement as shown in FIG. 2 is merely illustrative and explanatory, and these exemplary embodiments are not meant to preclude other arrangements from the scope of the present disclosure.

The polarizer 140 is attached on the glass substrate 130.

The array substrate 110 provides an electric field to the OLED layer 120 electric field. The provided electric field drives an organic semiconductor material and a light emitting material of the OLED layer 120 to emit light, such that the emitted light successively passes through the glass substrate 130 and then the polarizer 140, thereby displaying an image.

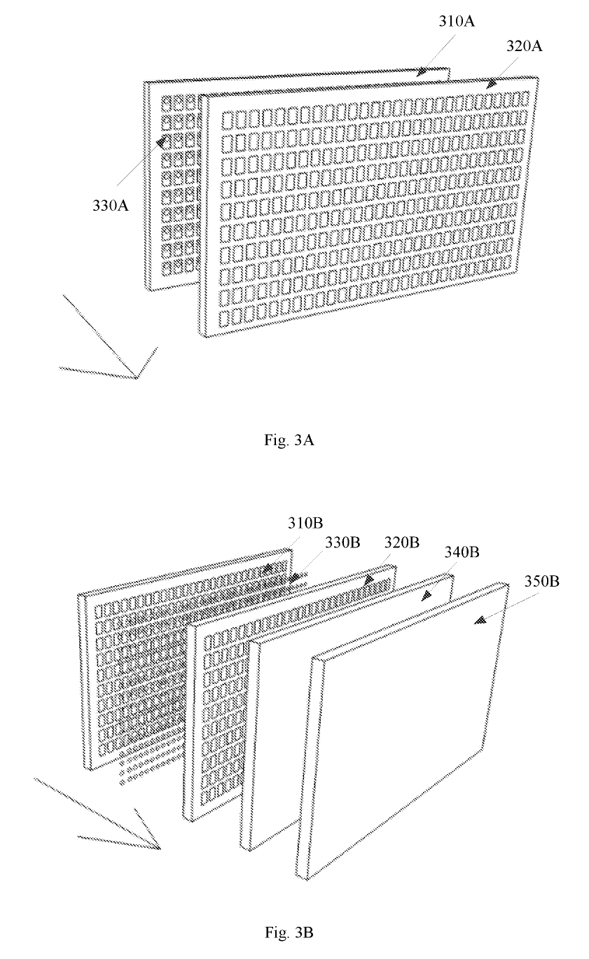

FIG. 3A is a schematic diagram showing an OLED panel according to an illustrative embodiment of the present disclosure. The OLED panel of FIG. 3A may be used for an electronic device such as a mobile phone, a tablet computer, or a laptop computer. As shown in FIG. 3A, an OLED panel may include an array substrate 310A, an OLED layer 320A, a photosensitive device array 330A, and a control circuit (not shown) connected to the photosensitive device array 330A. The OLED layer 320A is disposed on the array substrate 310A. The photosensitive device array 330A is disposed in the array substrate 310A. The photosensitive device array 330A may be disposed in the array substrate 310A by being co-planar with the array substrate 310A.

A glass substrate and polarizer (not shown) may be disposed on the OLED layer 320A, in a manner similar to that shown in FIG. 1.

One benefit of providing an OLED panel in which the photosensitive device array 330A is disposed in the array substrate 310A of the OLED panel is that such a configuration can allow for integration of a camera function into the OLED panel, such that a front panel including only the OLED panel may provide, simultaneously or at different times, both a display function and a camera function. Embodiments of the disclosure could thus solve a problem that ordinarily, to include a front facing camera in a terminal, the front panel of the terminal is divided into a plurality of regions, including one housing an aperture for a front facing camera, which may reduce the integral consistency and aesthetics of the terminal. Embodiments of the disclosure could increase the integral consistency and aesthetics of a terminal, for example, by providing a front panel that omits a division that houses an aperture for a front-facing camera, and instead using the OLED panel as the front-facing camera.

FIG. 3B is a schematic diagram showing an OLED panel according to another illustrative embodiment of the present disclosure. The OLED panel of FIG. 3B may be used for an electronic device such as a mobile phone, a tablet computer and a laptop computer. As shown in FIG. 3B, an OLED panel may include an array substrate 310B, an OLED layer 320B, a photosensitive device array 330B, and a control circuit (not shown) connected to the photosensitive device array 330B. OLED layer 320B is disposed on the array substrate 310B. Photosensitive device array 330B is disposed between the array substrate 310B and the OLED layer 320B.

A glass substrate 340B and a polarizer 350B may be disposed on the OLED layer 320B.

One benefit of providing an OLED panel in which the photosensitive device array 330B is disposed between the array substrate 310B and the OLED layer 320B is that such a configuration can allow for integration of a camera function into the OLED panel, such that a front panel including only the OLED panel may provide, simultaneously or at different times, both a display function and a camera function. Embodiments of the disclosure could thus solve a problem that ordinarily, to include a front facing camera in a terminal, the front panel of the terminal is divided into a plurality of regions, including one housing an aperture for a front-facing camera, which may reduce the integral consistency and aesthetics of the terminal. Embodiments of the disclosure could increase the integral consistency and aesthetics of a terminal, for example, by providing a front panel that omits a division that houses an aperture for a front-facing camera, and instead using the OLED panel as the front-facing camera. In an embodiment shown in FIG. 3A, the photosensitive device array 330A includes a×b photosensitive devices. Exemplary photosensitive devices may include individual photosensitive capacitors such as p-doped MOS capacitors useable as pixel sensors in charge-coupled devices (CCDs), individual active pixel sensor imagers useable as pixel sensors in complementary metal-oxide semiconductors (CMOSs), etc. The symbol a represents a number of columns of photosensitive devices, and the symbol b represents a number of rows of photosensitive devices. Each photosensitive device corresponds to one respective pixel sub-unit in the array substrate 310A, in which a≦K×m and b≦n. In a front view of the OLED panel, each photosensitive device is of a cross-section area less than an area occupied by one pixel sub-unit. During collecting of an image with such an embodiment, each photosensitive device is used to collect a respective photosensitive signal for one respective pixel sub-unit.

A number of photosensitive devices included in an OLED panel may be chosen according to the following two implementations.

1. In a first implementation, the number of photosensitive devices equals the number of pixel sub-units in the array substrate, i.e., a=K×m and b=n.

2. In a second implementation, the number of photosensitive devices is less than the number of pixel sub-units in the array substrate, i.e., a<K×m and b<n; or a<K×m and b=n; or a=K×m and b<n.

Depending upon the given chosen number of photosensitive devices, different exemplary positions of where photosensitive devices are located may be illustrated according to the following implementations.

1. In a first implementation, the photosensitive devices in the photosensitive device array correspond to the pixel sub-units in the array substrate in a one-to-one manner, in which a=K×m and b=n. In other words, each pixel sub-unit of the array substrate corresponds to one respective photosensitive device of the photosensitive device array, and the total number of photosensitive devices in the photosensitive device array equals the total number of pixel-subunits in the array substrate.

At least one photosensitive device may be located at the non-TFT region of a corresponding pixel sub-unit.

In general, in view of the sizes of photosensitive devices and of a circuit connected to the photosensitive devices, the photosensitive devices may preferably be located at respective non-TFT regions of the respective corresponding pixel sub-units. In some embodiments, however, the photosensitive devices may be located at respective TFT regions of the respective corresponding pixel sub-units.

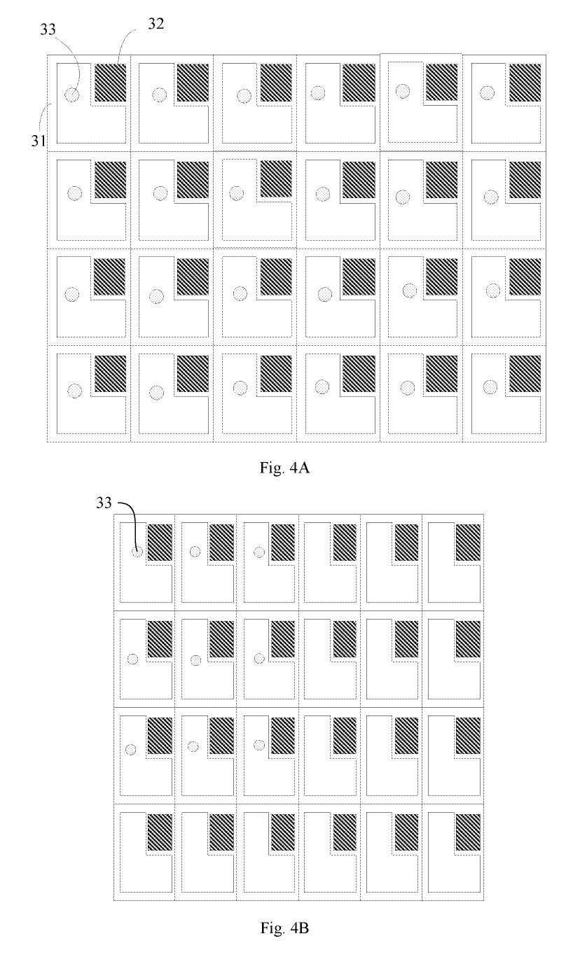

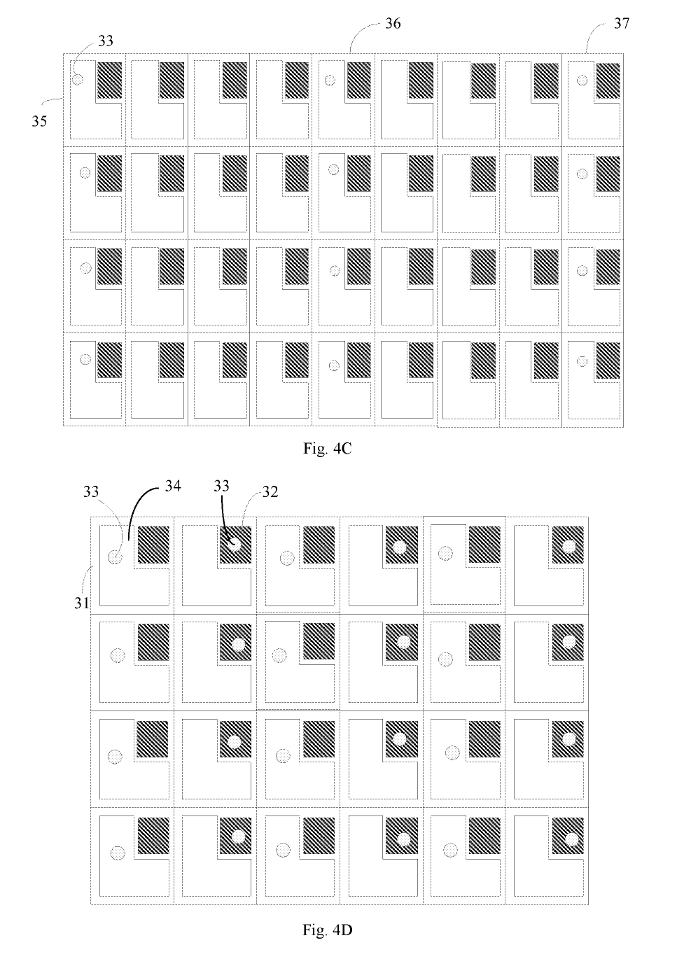

FIG. 4A is an example of the first implementation implemented in an embodiment with a photosensitive device array disposed in an array substrate. The array substrate includes 2 columns by 4 rows of pixel units 31, with each pixel unit 31 including 3 respective pixel subunits. Thus the array substrate includes 24 (3×2×4) pixel sub-units. The array substrate further includes 6 columns by 4 rows of photosensitive devices 33. Thus the photosensitive array disposed in the array substrate similarly includes 24 (6×4) photosensitive devices 33. The non-TFT region of each pixel sub-unit 31 is provided with one corresponding respective photosensitive device 33.

2. In a second implementation, the photosensitive device array is located at a sub-region of the array substrate, with the photosensitive devices in the photosensitive device array corresponding to the pixel sub-units in the sub-region in a one-to-one manner, in which a<K×m and b<n; or a<K×m and b=n; or a=K×m and b<n. In other words, each pixel sub-unit in the sub-region of the array substrate corresponds to one respective photosensitive device of the photosensitive device array, and the total number of photosensitive devices in the photosensitive device array is less than the total number of pixel sub-units in the array substrate.

At least one photosensitive device may be located at the non-TFT region of a corresponding pixel sub-unit.

FIG. 4B is an example of the second implementation implemented in an embodiment with a photosensitive device array disposed in an array substrate. The array substrate includes 2 columns by 4 rows of pixel units, with each pixel unit including 3 respective pixel sub-units. Thus the array substrate includes 24 (3×4×2) pixel sub-units. The array substrate further includes 3 columns by 3 rows of photosensitive devices. Thus the photosensitive device array disposed in the array substrate includes 9 (3×3) photosensitive devices. For the 9 pixel sub-units of the array substrate that are located at the sub-region, each pixel sub-unit is provided with one corresponding respective photosensitive device 33. For the pixel sub-units of the array substrate that are not located at the sub-region, no corresponding respective photosensitive devices are provided.

3. In a third implementation, photosensitive devices of the photosensitive device array are distributed throughout the entire region of the array substrate and separated from other photosensitive devices of the photosensitive device array, with each of the photosensitive devices corresponding to one respective pixel sub-unit in the array substrate, in which a<K×m and b<n; or a<K×m, b=n; or a=K×m and b<n. In other words, each photosensitive device corresponds to a respective pixel sub-unit in the array substrate, but there are gaps between photosensitive devices, and those gaps are filled by pixel sub-units that do not correspond to a pixel sub-unit, such that the total number of photosensitive devices of the photosensitive device array is less than the total number of pixel sub-units in the array substrate.

At least one photosensitive device may be located at the non-TFT region of the corresponding pixel sub-unit.

In the third implementation, the photosensitive devices correspond to some pixel sub-units in the array substrate. In other words, the photosensitive devices are distributed evenly throughout the entire region of the array substrate, but some of the pixel sub-units are provided with one photosensitive device, while other sub-pixel units are not provided with a photosensitive device.

FIG. 4C is an example of the third implementation implemented in an embodiment with a photosensitive device array disposed in an array substrate. The array substrate includes 3 columns by 4 rows of pixel units 31, with 3 pixel sub-units per pixel unit. Thus the array substrate includes 12 (3×4) pixel units and 36 (3×4×3) pixel sub-units. The array substrate further includes 3 columns by 4 rows of photosensitive devices 33. Thus the array substrate includes 12 (3×4) photosensitive devices 33. Taking as an example the first (or top) row of the array substrate, the first (or left-most) pixel sub-unit 35 in the first (or left-most) pixel unit is provided with one photosensitive device 33. The second (or middle) pixel sub-unit 36 in the second (or middle) pixel unit is provided with one photosensitive device 33. The third (or right-most) pixel sub-unit 37 in the third (or right-most) pixel unit is provided with one photosensitive device 33.

FIGS. 4A, 4B, and 4C described various implementations implemented in exemplary embodiments having a photosensitive device array disposed in an array substrate.

Alternatively, the photosensitive device array may be disposed between the array substrate and the OLED layer, with photosensitive devices being located above the corresponding pixel sub-units. For example, the photosensitive devices of a photosensitive device array may be located similarly to the photosensitive devices of one of the photosensitive device arrays shown in FIG. 4A, 4B, or 4C, but be located above the corresponding pixel sub-units.

In embodiments in which the photosensitive device array is disposed between the array substrate and the OLED layer, the photosensitive device is located above the corresponding pixel sub-unit. In other words a photosensitive device may be located above the respective TFT region of the respective corresponding pixel sub-unit, or may be located above the respective non-TFT region of the corresponding respective pixel sub-unit.

FIG. 4D is an example of an embodiment with the photosensitive device array disposed between the array substrate and the OLED layer. In FIG. 4D, some photosensitive devices 33 are located above the respective TFT region 32 of the corresponding respective pixel sub-unit, and other photosensitive devices 33 are located above the respective non-TFT region 34 of the corresponding respective pixel sub-unit.

FIGS. 4A-4D are merely some examples showing some positions at which photosensitive devices may be located. It will be apparent to those skilled in the art to determine other positions at which to locate the photosensitive devices, for example, based on combinations of the above described implementations. Other possible arrangements of positions are not precluded or otherwise limited by the exemplary embodiments of the present disclosure.

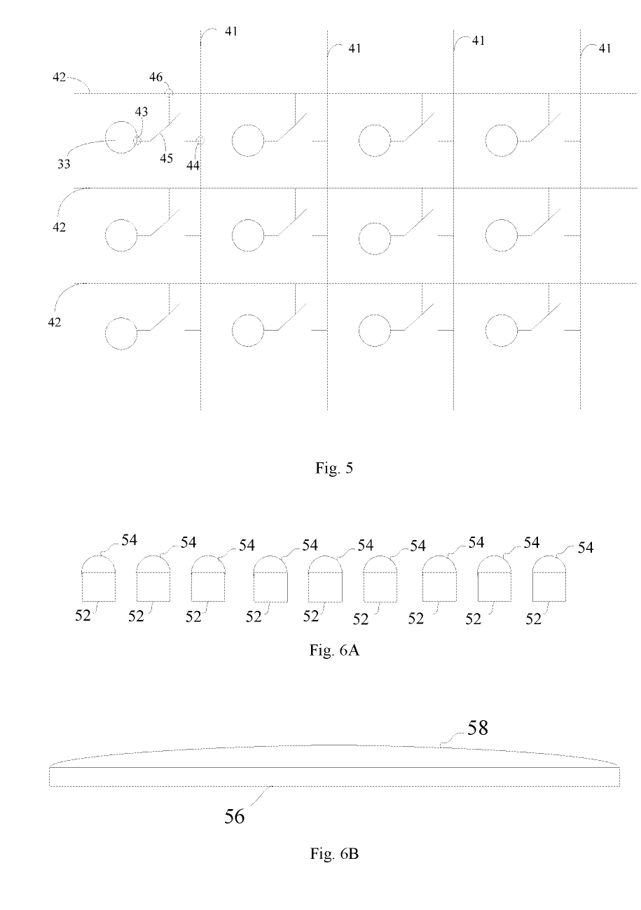

FIG. 5 is a schematic diagram showing a control circuit connected to a photosensitive device array. The control circuit includes a plurality of data lines 41 in a columns and a plurality of control lines 42 in b rows.

Each row of the plurality of the control lines 42 is connected to the plurality of the data lines 41 via the same number (i.e. a) of switches 45 as there are columns of data lines 41. In other words, a respective switch 45 connects each individual row of the control lines 42 to each of the a columns of data lines 41. Each switch 45 includes: a respective control terminal 46 connected to the corresponding control line 42; a respective first connecting terminal 43 connected to the corresponding photosensitive device 33; and a respective second connecting terminal 44 connected to the corresponding data line 41.

FIG. 5 depicts an embodiment in which the control circuit includes three rows of the control lines 42, four columns of the data lines 41, and 3 columns by 4 rows of photosensitive devices, i.e., 12 photosensitive devices. FIG. 5 is merely for illustration, and the specific numbers a or b are not limited to this exemplary embodiment.

The array substrate may also include K×m columns of the pixel data lines and n rows of the pixel control lines. Each pixel data line and pixel control line may be connected to a respective pixel sub-unit via a respective TFT device. A control circuit consisting of the pixel data line and the pixel control line for connecting to the TFT in the array substrate is similar to that shown in FIG. 5, but replaces photosensitive devices 33 with TFT regions 22, and is not elaborated in further detail herein.

Further embodiments are provided which are consistent with the embodiments of FIGS. 3A and 3B. For example, a respective lens may be disposed at a respective photosensitive side of each photosensitive device, i.e., the number of lenses may equal the number of photosensitive devices. As shown in FIG. 6A, a respective lens 54 is disposed on each photosensitive device 52. A lens 54 may be a semi-lens with a convex surface.

Alternatively, a lens may be disposed at the photosensitive side of the photosensitive device array, i.e., one single lens is disposed on the photosensitive device array and can cover all of the photosensitive devices of the photosensitive device array. As shown in FIG. 6B, one lens 58 is disposed at the photosensitive side of the photosensitive device array 56. Lens 58 may be a semi-lens with a convex surface. Lens 58 may be disposed on an upper polarizer such as the upper polarizer shown in FIG. 1.

In a present embodiment, a lens is disposed at a photosensitive side of a photosensitive device or a photosensitive side of a photosensitive device array, so that the photosensitive device may be of a wider photosensitive range, thereby achieving a better acquired image.

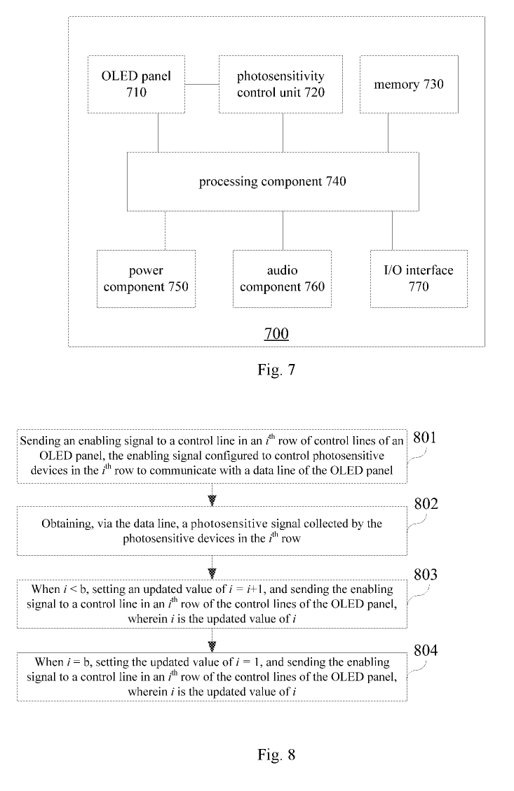

FIG. 7 is a block diagram showing a terminal according to an illustrative embodiment of the present disclosure. As shown in FIG. 7, the terminal 700 includes an OLED panel 710, a photosensitivity control unit 720, a memory 730, a processing component 740, a power component 750, an audio component 760, and an input/output (I/O) interface 770.

The OLED panel 710 may be any one of the OLED panels as shown in FIGS. 3A, 3B, 6A, and 6B, and may include features provided by the above embodiments, including features from FIGS. 4A-4D and 5.

The photosensitivity control unit 720 is connected to a control circuit in the OLED panel 710. The photosensitivity control unit 720 is connected to each data line in the control circuit, and further connected to each control line in the control circuit. The control circuit is connected to the photosensitive device array in the OLED panel 710.

The memory 730 is configured to store various types of data for supporting operations of the device 700. Examples of such data include instructions for any applications or methods operated on the device 700, contact data, phonebook data, messages, pictures, video, etc. The memory 730 may be implemented using any type of volatile or non-volatile memory devices, or a combination thereof, such as a static random access memory (SRAM), an electrically erasable programmable read-only memory (EEPROM), an erasable programmable read-only memory (EPROM), a programmable read-only memory (PROM), a read-only memory (ROM), a magnetic memory, a flash memory, a magnetic or optical disk.

The processing component 740 typically controls overall operations of the device 700, such as the operations associated with display, telephone calls, data communications, camera operations, and recording operations. The processing component 740 may include one or more processors to execute instructions to perform all or part of the steps in the above described methods. Moreover, the processing component 740 may include one or more modules which facilitate the interaction between the processing component 740 and other components.

The power component 750 provides power to various components of the device 700. The power component 750 may include a power management system, one or more power sources, and any other components associated with the generation, management, and distribution of power in the device 700.

The audio component 760 is configured to output and/or input audio signals. For example, the audio component 760 includes a microphone (MIC) configured to receive an external audio signal when the device 700 is in an operation mode, such as a call mode, a recording mode, and a voice recognition mode. The received audio signal may be further stored in the memory 730. In some embodiments, the audio component 760 further includes a speaker to output audio signals.

The I/O interface 770 provides an interface for the processing component 740 and peripheral interface modules, such as a keyboard, a click wheel, buttons, and the like. The buttons may include, but are not limited to, a home button, a volume button, a starting button, and a locking button.

FIG. 8 is a flow chart showing a method for controlling photosensitivity according to an illustrative embodiment of the present disclosure. In a present exemplary embodiment, a method for controlling the photosensitivity is being executed in the photosensitivity control unit 720 inside a terminal 700. A method may include the following steps.

In step 801, an enabling signal is sent to the control line in the i^{th} row, the enabling signal configured to control the photosensitive devices in the i^{th} row to communicate with one or more data lines.

The enabling signal is configured to control the photosensitive devices in the i^{th} row to communicate with one or more data lines. The photosensitivity control unit sends the enabling signal to the control line in the i^{th} row of the control circuit. The enabling signal causes the photosensitive devices in the i^{th} row to communicate with the one or more data lines of the control circuit.

In the exemplary control circuit shown in FIG. 5, the control circuit includes four columns of the data lines 41, three rows of the control lines 42, and four photosensitive devices 33 in each row (i.e., 12 photosensitive devices 33 in total). When the photosensitivity control unit sends the enabling signal to the control line 42 in the first row, the four switches 45 in the first row are all set to an ON state, and each of the four photosensitive devices 33 in the first row communicates with the corresponding data line 41.

In step 802, one or more photosensitive signals collected by the photosensitive devices in the i^{th} row are obtained via the one or more data lines.

The photosensitivity control unit obtains the one or more photosensitive signal collected by the photosensitive devices in the i^{th} row via the one or more data lines. After being collected by the photosensitive devices, the one or more photosensitive signals are transmitted to the photosensitivity control unit through communication over the one or more data lines.

In the exemplary control circuit shown in FIG. 5, the control circuit includes four columns of the data lines 41, three rows of the control lines 42, and four photosensitive devices 33 in each row (i.e., 12 photosensitive devices 33 in total). After the four photosensitive devices 33 in the first row begin communicating with the data line 41, the photosensitivity control unit may obtain the respective photosensitive signals collected by four photosensitive devices 33 via the four respective columns of the data lines 41.

The one or more photosensitive signals obtained by the photosensitivity control unit may be one or more analog signals. The one or more analog signals may be converted to one or more digital signals by an analog-digital converter, and the one or more digital signals may be stored in a memory.

In step 803, when the current i is less than b, an updated i is set as i+1 and the enabling signal is sent to the control line in the i^{th} row, where i is the updated value of i.

The symbol i represents the row number of a control line with which the photosensitivity control unit is communicating at a given time, and b represents the total number of rows. When i is less than b, and the photosensitivity control unit is ready to control another control line, i is updated by being set as i+1 and the photosensitivity control unit sends the enabling signal to the control line in the (i+1)^{th} row. When i=b, step 804 is performed.

In the exemplary control circuit shown in FIG. 5, the control circuit includes three rows of the control lines. Once the photosensitivity control unit has sent the enabling signal to the control line in the first row for a predetermined time period, the photosensitivity control unit may be ready to control another line. In this example, i=1, b=3, and i<3, so i is updated by being set as 2, and the enabling signal is then sent to the control line in the second row. This process is repeated until the enabling signal has been sent to the control line in the third row. That is, the photosensitivity control unit sends the enabling signal to respective control lines in a row-by-row manner at intervals of the predetermined time period.

In step 804, when i equals b, i is updated by being set as 1, and the enabling signal is sent to the control line in the i^{th} row, where i has been updated to 1.

When i equals b, i is updated by being set as 1, and the photosensitivity control unit sends the enabling signal to the control line in the first row. That is, after the photosensitivity control unit has sent the enabling signal to all rows of the control lines, the enabling signal is again sent to the control line of the first row.

Step 801 is performed again after completing step 804. That is, steps 801 to 804 are performed in a loop. When i is of an initial value of 1, the enabling signal is sent to the respective control lines in a row-by-row manner, from the first row until the last row, so as to collect the one or more photosensitive signals corresponding to a current frame. Subsequently, the photosensitivity control unit repeats sending the enabling signal to the respective control lines in a row-by-row manner, from the first row until the last row, so as to collect the one or more photosensitive signals corresponding to a next frame.

Thus in exemplary methods for controlling the photosensitivity provided by embodiments of the present disclosure, the photosensitivity control unit continuously sends the enabling signal to the respective control lines in the control circuit in a row-by-row manner, so that the photosensitive devices in the control circuit are in communication with the data line. The photosensitivity control unit obtains the respective one or more photosensitive signals via the control line currently in the ON state, and processes the one or more photosensitive signals. Embodiments of this disclosure thus may allow for integration of a camera function into the OLED panel, such that a front panel including only the OLED panel may provide, simultaneously or at different times, both a display function and a camera function. Such integration could increase the integral consistency and aesthetics of a terminal, for example, by providing a front panel that omits a division that houses an aperture for a front-facing camera, and instead using the OLED panel as the front-facing camera.

The methods described above in connection with FIG. 8 may be implemented in many different ways and as hardware, software or in different combinations of hardware and software. For example, all or parts of the implementations may be a processing circuitry that includes an instruction processor, such as a central processing unit (CPU), microcontroller, a microprocessor; or application specific integrated circuits (ASICs), digital signal processors (DSPs), digital signal processing devices (DSPDs), programmable logic devices (PLDs), field programmable gate arrays (FPGAs), controllers, micro-controllers, microprocessors, other electronic components; or as circuitry that includes discrete logic or other circuit components, including analog circuit components, digital circuit components or both; or any combination thereof. The circuitry may include discrete interconnected hardware components or may be combined on a single integrated circuit die, distributed among multiple integrated circuit dies, or implemented in a Multiple Chip Module (MCM) of multiple integrated circuit dies in a common package, as examples.

Processing steps discussed above, such as step 801, step 802, step 803, and step 804, may be implemented through use of a corresponding respective module configured to perform each of those steps, which may take the form of a packaged functional hardware unit designed for use with other components, a portion of a program code (e.g., software or firmware) executable by the one or more processors of processing component 740 or the processing circuitry that usually performs a particular function of related functions, or a self-contained hardware or software component that interfaces with a larger system, for example.

Other embodiments of the disclosure will be apparent to those skilled in the art from consideration of the specification and practice of the disclosure disclosed here. This application is intended to cover any variations, uses, or adaptations of the disclosure following the general principles thereof and including such departures from the present disclosure as come within known or customary practice in the art. It is intended that the specification and examples be considered as illustrative only, with a true scope and spirit of the disclosure being indicated by the following claims.

It will be appreciated that the present disclosure is not limited to the exact constructions that have been described above and illustrated in the accompanying drawings, and that various modifications and changes can be made without departing form the scope thereof. It is intended that the scope of the disclosure only be limited by the appended claims.

What is claimed is:

1. An organic light emitting display (OLED) panel, comprising:
an array substrate;
an OLED layer disposed on the array substrate;
a photosensitive device array disposed in the array substrate or disposed between the array substrate and the OLED layer; and
a control circuit connected to the photosensitive device array.

2. The OLED panel of claim 1, wherein:
the array substrate comprises m×n pixel units, wherein m is a number of columns of pixel units of the array substrate, wherein n is a number of rows of pixel units of the array substrate, and wherein each of the pixel units comprises K respective pixel sub-units; and
the photosensitive device array comprises a×b photosensitive devices, wherein a is a number of columns of photosensitive devices in the photosensitive device array, wherein b is a number of rows of photosensitive devices in the photosensitive device array, wherein each of the photosensitive devices corresponds to one respective pixel sub-unit, and wherein a≦K×m and b≦n.

3. The OLED panel of claim 2, wherein:
each of the photosensitive devices corresponds to one respective pixel sub-unit in the array substrate, wherein a=K×m and b=n.

4. The OLED panel of claim 2, wherein:
the photosensitive device array is located at a sub-region of the array substrate, wherein each of the photosensitive devices corresponds to one respective pixel sub-unit in the sub-region, and wherein: a<K×m and b<n; or a<K×m and b=n; or a=K×m and b<n.

5. The OLED panel of claim 2, wherein:
the photosensitive device array is disposed in the array substrate;
each of the pixel sub-units comprises a respective thin film transistor (TFT) region and a respective non-TFT region; and
at least one of the photosensitive devices is located at a non-TFT region of a corresponding pixel sub-unit.

6. The OLED panel of claim 2, wherein:
the photosensitive device array is disposed between the array substrate and the OLED layer; and
each of the photosensitive devices is located above a respective region of a corresponding respective pixel sub-unit.

7. The OLED panel of claim 2, wherein:
the control circuit comprises a plurality of data lines in a columns and a plurality of control lines in b rows;
each row of the plurality of control lines is connected to the plurality of data lines via a switches; and
for each switch of the a switches:
a respective control terminal of the switch is connected to a corresponding control line,
a respective first connecting terminal of the switch is connected to a corresponding photosensitive device, and
a respective second connecting terminal of the switch is connected to a corresponding data line.

8. The OLED panel of claim 1, wherein each photosensitive device is provided with a lens at a respective photosensitive side of the photosensitive device.

9. The OLED panel of claim 1, further comprising:
a glass substrate disposed on the OLED layer;
a polarizer disposed on the glass substrate; and
a lens disposed on the polarizer.

10. The OLED panel of claim 1, further comprising a photosensitivity control unit connected to the control circuit, the photosensitivity control unit configured to:
send an enabling signal to a control line in an i^{th} row of b rows of a plurality of control lines of the control circuit, the enabling signal configured to control photosensitive devices in the i^{th} row to communicate with a data line of the control circuit, wherein 0<i≦b;
obtain, via the data line, a photosensitive signal collected by the photosensitive devices in the i^{th} row;
after sending the enabling signal to the control line in the i^{th} row, generate an updated value of i by:
when i<b, setting the updated value of i=i+1, and
when i=b, setting the updated value of i=1; and
send the enabling signal to a control line in an i^{th} row of the b rows of the plurality of control lines of the control circuit, wherein i is the updated value of i.

11. A method for controlling photosensitivity, comprising:
with a photosensitivity control unit connected to an organic light emitting display (OLED) panel:
sending an enabling signal to a control line in an i^{th} row of b rows of a plurality of control lines of the OLED panel, the enabling signal configured to control photosensitive devices in the i^{th} row to communicate with a data line of the OLED panel, wherein 0<i≦b;
obtaining, via the data line, a photosensitive signal collected by the photosensitive devices in the i^{th} row;
after sending the enabling signal to the control line in the i^{th} row, generating an updated value of i by:
when i<b, setting the updated value of i=i+1, and
when i=b, setting the updated value of i=1; and
sending the enabling signal to a control line in an i^{th} row of the b rows of the plurality of control lines of the OLED panel, wherein i is the updated value of i.

12. The method of claim 11, wherein the OLED panel comprises:
an array substrate;
an OLED layer disposed on the array substrate;
a photosensitive device array disposed in the array substrate or disposed between the array substrate and the OLED layer; and
a control circuit connected to the photosensitive device array

13. The method of claim 12, wherein:
the array substrate comprises m×n pixel units, wherein m is a number of columns of pixel units of the array substrate, wherein n is a number of rows of pixel units of the array substrate, and wherein each of the pixel units comprises K respective pixel sub-units; and
the photosensitive device array comprises a×b photosensitive devices, wherein a is a number of columns of photosensitive devices in the photosensitive device array, wherein b is a number of rows of photosensitive devices in the photosensitive device array, wherein each of the photosensitive devices corresponds to one respective pixel sub-unit, and wherein a≦K×m and b≦n.

14. The method of claim 13, wherein:
each of the photosensitive devices corresponds to one respective pixel sub-unit in the array substrate, wherein a=K×m and b=n.

15. The method of claim 13, wherein:
the photosensitive device array is located at a sub-region of the array substrate, wherein each of the photosensitive devices corresponds to one respective pixel sub-unit in the sub-region, and wherein: a<K×m and b<n; or a<K×m and b=n; or a=K×m and b<n.

16. The method of claim 13, wherein:
the photosensitive device array is disposed in the array substrate;
each of the pixel sub-units comprises a respective thin film transistor (TFT) region and a respective non-TFT region; and
at least one of the photosensitive devices is located at a non-TFT region of a corresponding pixel sub-unit.

17. The method of claim 13, wherein:
the photosensitive device array is disposed between the array substrate and the OLED layer; and
each of the photosensitive devices is located above a respective region of a corresponding pixel sub-unit.

18. The method of claim 13, wherein:
the control circuit comprises a plurality of data lines in a columns and the plurality of control lines in the b rows;
each row of the plurality of control lines is connected to the plurality of data lines via a switches; and
for each switch of the a switches:
a respective control terminal of the switch is connected to a corresponding control line,
a respective first connecting terminal of the switch is connected to a corresponding photosensitive device, and
a respective second connecting terminal of the switch is connected to a corresponding data line.

19. The method of claim 18, wherein the photosensitivity control unit is connected to each of the plurality of data lines and each of the plurality of control lines.

20. The method of claim 12, wherein each photosensitive device is provided with a lens at a respective photosensitive side of the photosensitive device.

21. The method of claim 12, further comprising:
a glass substrate disposed on the OLED layer;
a polarizer disposed on the glass substrate; and
a lens disposed on the polarizer.

22. A terminal comprising:
an organic light emitting display (OLED) panel;
a processor; and
a memory for storing instructions executable by the processor;
wherein the processor is configured to:
send an enabling signal to a control line in an i^{th} row of b rows of a plurality of control lines of the OLED panel, the enabling signal configured to control photosensitive devices in the i^{th} row to communicate with a data line of the OLED panel, wherein 0<i≦≦b;
obtain, via the data line, a photosensitive signal collected by the photosensitive devices in the i^{th} row;
after sending the enabling signal to the control line in the i^{th} row, generate an updated value of i by:
when i<b, setting the updated value of i=i+1, and
when i=b, setting the updated value of i=1; and
send the enabling signal to a control line in an i^{th} row of the b rows of the plurality of control lines of the OLED panel, wherein i is the updated value of i.
